(19) United States
(12) Patent Application Publication
(10) Pub. No.: US 2026/0075711 A1
(43) Pub. Date: Mar. 12, 2026

(54) PRINTED CIRCUIT BOARD

(71) Applicant: SAMSUNG ELECTRO-MECHANICS CO., LTD., Suwon-si (KR)

(72) Inventors: Sang Ho Jeong, Suwon-si (KR); Chang Hwa Park, Suwon-si (KR); Sang Yun Lee, Suwon-si (KR); Hyun Hu Lee, Suwon-si (KR)

(73) Assignee: SAMSUNG ELECTRO-MECHANICS CO., LTD., Suwon-si (KR)

(21) Appl. No.: 19/235,490

(22) Filed: Jun. 11, 2025

(30) Foreign Application Priority Data
Sep. 6, 2024 (KR) 10-2024-0121374
Dec. 13, 2024 (KR) 10-2024-0185920

(51) Int. Cl. H05K 1/11; H05K 1/18

(52) U.S. Cl. CPC H05K 1/113; H05K 1/181; H05K 2201/0215; H05K 2201/09481; H05K 2201/09527; H05K 2201/096; H05K 2201/09618; H05K 2201/09827

(57) ABSTRACT

A printed circuit board includes a first wiring portion including a first insulating layer and a first conductor layer disposed on at least one surface of the first insulating layer; a second wiring portion including a second insulating layer and a second conductor layer disposed on at least one surface of the second insulating layer facing the one surface of the first insulating layer; a bonding portion disposed between the first and second wiring portions to connect the first and second wiring portions, and including a bonding layer and a conductive filler dispersed within the bonding layer; and a first insulating film disposed on a portion of the first conductor layer.

### CROSS-REFERENCE TO RELATED APPLICATIONS

This application claims benefit of priority to Korean Patent Application Nos. 10-2024-0121374 filed on Sep. 6, 2024 and 10-2024-0185920 filed on Dec. 13, 2024 in the Korean Intellectual Property Office, the disclosures of which are incorporated herein by reference in its entirety.

### BACKGROUND

### 1. Filled

The present disclosure relates to a printed circuit board.

### 2. Description of Related Art

Recently, due to the development of artificial intelligence (AI) technology, a package including a memory chip such as a high bandwidth memory (HBM) for exponentially increased data processing and a processor chip such as a central processing unit (CPU), a graphics processing unit (GPU), an application specific integrated circuit (ASIC), and a filled programmable gate array (FPGA) may be used.

Research has been conducted to reduce defects occurring while a chip is mounted and to improve yield in a printed circuit board used in such a package. As the number of laminations of a substrate increases, a defect rate per layer may accumulate, which may lower overall yield, and the decrease in yield may be greater in a substrate requiring fine circuits.

### SUMMARY

An example embodiment of the present disclosure is to provide a printed circuit board of which reliability may be improved in coupling a plurality of wiring portions to each other.

According to an example embodiment, a printed circuit board includes a first wiring portion including a first insulating layer and a first conductor layer disposed on at least one surface of the first insulating layer; a second wiring portion including a second insulating layer and a second conductor layer disposed on at least one surface of the second insulating layer facing the one surface of the first insulating layer; a bonding portion disposed between the first and second wiring portions to connect the first and second wiring portions, and including a bonding layer and a conductive filler dispersed within the bonding layer; and a first insulating film disposed on a portion of the first conductor layer.

The first insulating film may include at least one of Al₂O₃, ZnO, TiO₂, and SiO₂.

The first insulating film may be an atomic layer deposition layer.

A thickness of the first insulating film may be 5 nm to 15 nm.

The first insulating film may also be disposed on the one surface of the first insulating layer.

The first insulating film may expose at least a portion of the one surface of the first insulating layer.

The first insulating film may be in contact with the conductive filler.

The first insulating film may be coated on a portion of the first conductor layer.

The first insulating film may be a surface oxide layer of the first conductor layer.

A region of the first conductor layer on which the first insulating film is disposed may be thicker than a region of the first conductor layer which is free of the first insulating film.

The bonding portion may be in contact with a surface of the region of the first conductor layer which is free of the first insulating film and a side surface of the first insulating film.

A region of the first conductor layer which is free of the first insulating film may have a step structure with respect to the region of the first conductor layer on which the first insulating film is disposed.

A region of the first conductor layer which is free of the first insulating film may have a groove shape with respect to the region of the first conductor layer on which the first insulating film is disposed.

The bonding portion may be disposed in the groove-shaped region of the first conductor layer.

A pitch of the first conductor layer may be narrower than a pitch of the second conductor layer.

The second wiring portion may further include a second insulating film disposed on a portion of the second conductor layer.

A first exposed region of the first conductor layer exposed by the first insulating film and a second exposed region of the second conductor layer exposed by the second insulating film may be connected by the conductive filler.

A side surface of the first insulating layer is free of the first insulating film, and a side surface of the second insulating layer is free of the second insulating film.

Widths of the first insulating layer and the second insulating layer may be substantially the same.

The first insulating film extends to a side surface of the first insulating layer, and a side surface of the second insulating layer is free of the second insulating film.

A width of the first insulating layer may be narrower than a width of the second insulating layer.

The first wiring portion may further include a third conductor layer disposed on the other surface of the first insulating layer opposite to the one surface of the first insulating layer, and a third insulating film disposed on a portion of the third conductor layer.

The second wiring portion may further include a fourth conductor layer disposed on the other surface of the second insulating layer opposite to the one surface of the second insulating layer, and a fourth insulating film disposed on a portion of the fourth conductor layer.

According to an example embodiment, a printed circuit board includes a first wiring portion including a first insulating layer and a first conductor layer including a first pad region and a first wiring pattern disposed on one surface of the first insulating layer; a second wiring portion including a second insulating layer and a second conductor layer including a second pad region and a second wiring pattern disposed on one surface of the second insulating layer; a first insulating film disposed on a portion of the first conductor layer; and a bonding portion disposed between the first and second wiring portions to connect the first and second wiring portions, and including a bonding layer and conductive particles dispersed within the bonding layer. One of the conductive particles disposed between the first pad region and the second pad region is in contact with one or both of the first pad region and the second pad region, and another of the conductive particles disposed between the first wiring pattern and the second wiring pattern is in contact with the first insulating film.

A region of the first conductor layer where the one conductive particle is disposed may be thinner than a region of the first conductor layer where the another conducive particle is disposed.

The first pad region may be partially covered with the first insulating film.

A portion of the first pad region covered by the first insulating layer may be thicker than a portion of the first pad region being in contact with the one conductive particle.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating an example of a printed circuit board;

FIGS. 4 to 7 illustrate examples of a manufacturing process of a printed circuit board;

FIG. 8 is a cross-sectional view schematically illustrating an example of a printed circuit board;

FIG. 9 is a cross-sectional view schematically illustrating an example of a printed circuit board;

FIG. 10 is a cross-sectional view schematically illustrating an example of a printed circuit board;

FIG. 11 is a cross-sectional view schematically illustrating an example of a printed circuit board;

FIG. 12 illustrates an example of a manufacturing process of a printed circuit board;

FIG. 13 is a cross-sectional view schematically illustrating an example of a printed circuit board;

FIG. 14 is a cross-sectional view schematically illustrating an example of a printed circuit board;

FIG. 15 is a cross-sectional view schematically illustrating an example of a printed circuit board; and

FIG. 16 is a cross-sectional 1 view schematically illustrating an example of a printed circuit board.

### DETAILED DESCRIPTION

Hereinafter, embodiments of the present disclosure will be described as follows with reference to the attached drawings. The present disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art. Accordingly, shapes and sizes of elements in the drawings may be exaggerated for clear description, and elements indicated by the same reference numerals are the same elements in the drawings.

### Electronic Device

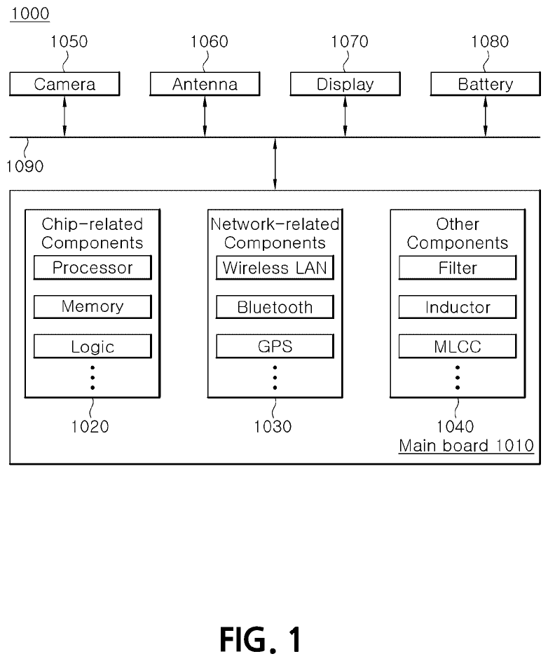

FIG. 1 is a block diagram schematically illustrating an example of an electronic device system.

Referring to FIG. 1, an electronic device 1000 may accommodate a mainboard 1010 therein. The mainboard 1010 may include chip related components 1020, network related components 1030, other components 1040, and the like, physically or electrically connected thereto. These components may be connected to others to be described below to form various signal lines 1090.

The chip related components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital (ADC) converter, an application-specific integrated circuit (ASIC), or the like. However, the chip related components 1020 are not limited thereto, and may also include other types of chip related components. Also, the chip related components 1020 may be combined with each other.

The network related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols, designated after the abovementioned protocols. However, the network related components 1030 are not limited thereto, and may also include a variety of other wireless or wired standards or protocols. Also, the network related components 1030 may be combined with each other, together with the chip related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, and may also include passive components used for various other purposes, or the like. Also, other components 1040 may be combined with each other, together with the chip related components 1020 and/or the network related components 1030 described above.

Depending on a type of the electronic device 1000, the electronic device 1000 may include other components which may or may not be physically or electrically connected to the mainboard 1010. The other components may include, for example, a camera module 1050, an antenna module 1060, a display 1070, and a battery 1080. However, the other components are not limited thereto, and may include an audio codec, a video codec, a power amplifier, a compass, an accelerometer, a gyroscope, a speaker, a mass storage unit (for example, a hard disk drive), a compact disk (CD) drive, a digital versatile disk (DVD) drive, or the like. The other components may also include other components used for various purposes depending on a type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device processing data.

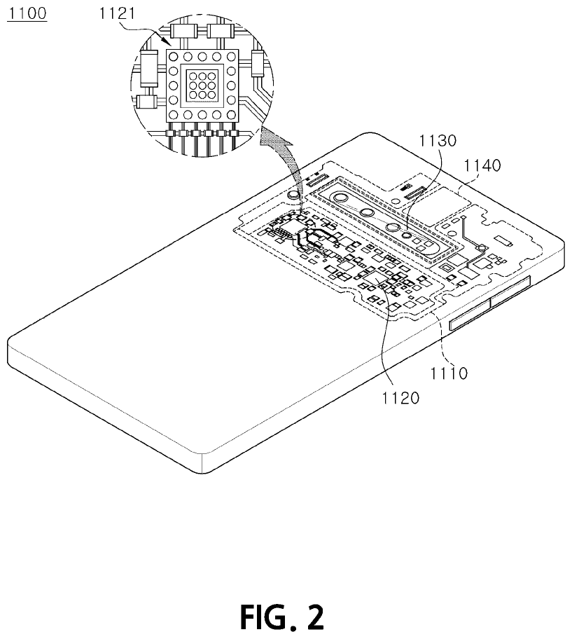

FIG. 2 is a perspective view schematically illustrating an example of an electronic device.

Referring to FIG. 2, an electronic device may be a smartphone 1100. A motherboard 1110 may be accommodated in the smartphone 1100, and various components 1120 may be physically or electrically connected to the motherboard 1110. Also, other components which may or may not be physically or electrically connected to the motherboard 1110, such as a camera module 1130, may be accommodated in the body 1101. A portion of the components 1120 may be the chip related components, such as, for example, a component package 1121, but an example embodiment example thereof is not limited thereto. The component package 1121 may have the form of a printed circuit board on which electronic components including active components and/or passive components are surface-mounted. Alternatively, the component package 1121 may be configured in the form of a printed circuit board in which active components and/or passive components are buried. The electronic device is not necessarily limited to the smartphone 1100, and may be other electronic devices as described above.

### Printed Circuit Board

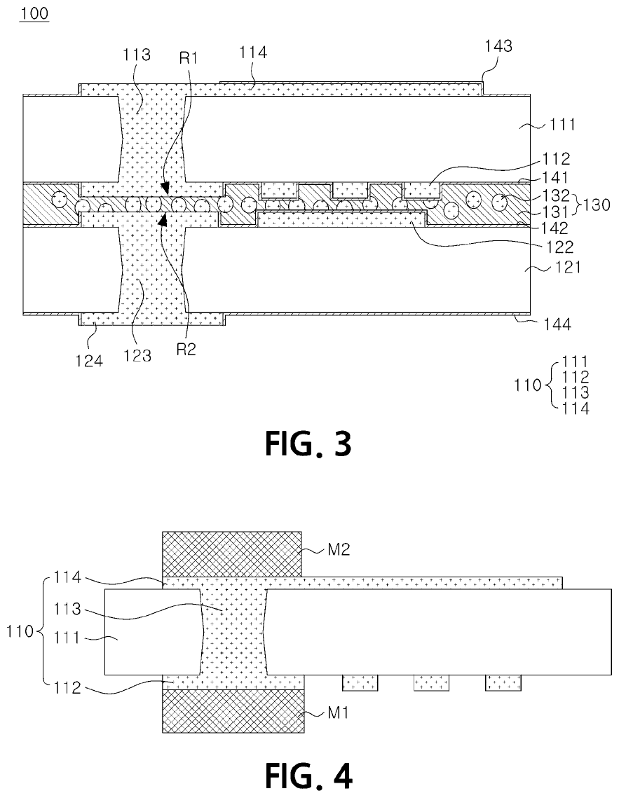

FIG. 3 is a cross-sectional view schematically illustrating an example of a printed circuit board. Referring to FIG. 3, a printed circuit board 100 according to the present embodiment includes a first wiring portion 110 and a second wiring portion 120, and the first and second wiring portions 110 and 120 are connected by a bonding portion 130 including a bonding layer 131 and a conductive filler 132. Here, the first wiring portion 110 includes a first insulating layer 111 and a first conductor layer 112, the second wiring section 120 includes a second insulating layer 121 and a second conductor layer 122, and a first insulating film 141 formed in a portion of the first conductor layer 112 is provided. Likewise, a second insulating film 142 formed in a portion of the second conductor layer 122 may be provided, and the description of the first insulating film 141 below may also be applied to the second insulating film 142. As in the present embodiment, when connecting the first and second wiring portions 110 and 120, by forming the first insulating layer 141 in a portion of the first conductor layer 112, an unintended electrical connection may be prevented from occurring between the first conductor layer 112 and the second conductor layer 122, thereby improving the electrical reliability of the printed circuit board 100. Hereinafter, the main components of the printed circuit board 100 may be described in greater detail.

The first wiring portion 110 includes a first insulating layer 111 and a first conductor layer 112, and in each layer, a plurality of layers are stacked. However, the first insulating layer 111 and the first conductor layer 112 may be implemented as a single-layer structure, and for example, the first wiring portion 110 may be coupled to the second wiring portion 120 as a single-layer build-up layer. The first insulating layer 111 may include an insulating material such as an insulating resin, such as a thermosetting resin such as an epoxy resin or a thermoplastic resin such as a polyimide, or a material in which the resins are mixed with an inorganic filler such as silica, or a resin impregnated into a core material such as glass fiber, glass cloth, glass fabric, or the like, together with an inorganic filler, for example, an Ajinomoto Build-up Film (ABF), prepreg, or the like. If necessary, the first insulating layer 111 may include a Photo Imageable Dielectric (PID). The first insulating layer 111 may be obtained by stacking a plurality of insulating layers, wherein the plurality of insulating layers may include the same or different insulating materials.

The first conductor layer 112 may be disposed on at least one surface of the first insulating layer 111, and may include a metal material such as copper (Cu), aluminum (Al), silver (Ag), tin (Sn), gold (Au), nickel (Ni), lead (Pb), titanium (Ti), or an alloy thereof. The first conductor layer 112 may include an electroless plating layer and an electrolytic plating layer, and may further include a copper foil if necessary. The first conductor layer 112 may perform various functions depending on the design of a corresponding layer. For example, the first conductor layer 112 may include a ground pattern, a power pattern, a signal pattern, or the like. Here, the signal pattern may include various signals, such as a data signal, other than a ground pattern, a power pattern, or the like. Each of the patterns may include a trace, a plane, and/or a pad. The first conductor layer 112 may be disposed in a multilayer structure on a surface and inside of the first insulating layer 111, and in the embodiment, a layer disposed on one surface of the first insulating layer 111 is referred to as a first conductor layer 112, and a layer disposed on the other surface of the first insulating layer 111 is referred to as a third conductor layer 114.

A first via 113 may be provided to connect the first conductor layer 112 and the third conductor layer 114. The first via 113 may include copper (Cu), aluminum (Al), silver (Ag), tin (Sn), gold (Au), nickel (Ni), lead (Pb), titanium (Ti), or an alloy thereof as a metal material. The first via 113 may be formed together with the first conductor layer 112, and may include an electroless plating layer and an electrolytic plating layer. The first via 113 may be a filled-type via in which a through-hole of the first insulating layer 111 is filled with a metal material, but an example embodiment thereof is not limited thereto, and the first via 113 may also be a conformal-type via in which a metal material is disposed along a wall surface of the through-hole. The first via 113 may have a tapered shape in a cross-section. The first via 113 may perform various functions depending on the design of a corresponding layer. For example, the first via 113 may include a ground via, power via, signal via, or the like. Here, the signal via may include a via for transmitting various signals, such as a data signal, other than a ground via, a power via, or the like.

Similarly to the first wiring portion 110, the second wiring portion 120 includes a second insulating layer 121 and a second conductor layer 122, in each layer, a plurality of layers are stacked. However, the second insulating layer 121 and the second conductor layer 122 may be implemented as a single-layer structure, and for example, the second wiring portion 120 may be coupled to the first wiring portion 110 as a single-layer build-up layer. The second insulating layer 121 may include an insulating material, such as a thermosetting resin such as an epoxy resin, a thermoplastic resin such as a polyimide, or a material in which these resins are mixed with an inorganic filler such as silica, or a resin impregnated into a core material such as glass fiber, glass cloth, glass fabric, or the like, together with an inorganic filler, for example, Ajinomoto build-up film (ABF), prepreg, or the like. If necessary, the second insulating layer 121 may include a Photo Imageable Dielectric (PID). The second insulating layer 121 may be obtained by stacking a plurality of insulating layers. The plurality of insulating layers may include the same or different insulating materials.

The second conductor layer 122 may be disposed on at least one surface of the second insulating layer 121, and may include a metal material such as copper (Cu), aluminum (Al), silver (Ag), tin (Sn), gold (Au), nickel (Ni), lead (Pb), titanium (Ti), or an alloy thereof. The second conductor layer 122 may include an electroless plating layer and an electrolytic plating layer, and may further include a copper foil if necessary. The second conductor layer 122 may perform various functions depending on the design of a corresponding layer. For example, the second conductor layer 122 may include a ground pattern, a power pattern, a signal pattern, or the like. Here, the signal pattern may include various signals, such as a data signal, other than a ground pattern, a power pattern, or the like. Each of the patterns may include a trace, a plane, and/or a pad. The second conductor layer 122 may be disposed in a multilayer structure on a surface and inside of the second insulating layer 121, and in the embodiment, a layer disposed on one surface of the second insulating layer 121 is referred to as a second conductor layer 122, and a layer disposed on the other surface of the second insulating layer 121 is referred to as a fourth conductor layer 124.

A second via 123 may be provided to connect the second conductor layer 122 and the fourth conductor layer 124. The second via 123 may include copper (Cu), aluminum (Al), silver (Ag), tin (Sn), gold (Au), nickel (Ni), lead (Pb), titanium (Ti), or an alloy thereof as a metal material. The second via 123 may be formed together with the second conductor layer 122, and may include an electroless plating layer and an electrolytic plating layer. The second via 123 may be a filled-type via in which a through-hole of the second insulating layer 121 is filled with a metal material, but an example embodiment thereof is not limited thereto, and the second via 123 may also be a conformal-type via in which a metal material is disposed along a wall surface of the through-hole. The second via 123 may have a tapered shape in a cross-section. The second via 123 may perform various functions depending on the design of a corresponding layer. For example, the second via 123 may include a ground via, power via, signal via, or the like. Here, the signal via may include a via for transmitting various signals, such as a data signal, other than a ground via, a power via, or the like.

The bonding portion 130 is disposed between the first and second wiring portions 110 and 120 to connect the first and second wiring portions 110 and 120, and in addition to this bonding function, may also serve as a path for electrical connection. To this end, the bonding portion 130 includes a bonding layer 131 and a conductive filler 132 dispersed within the bonding layer 131. The bonding layer 131 may include an insulating resin, and may include a thermally polymerizable compound such as an epoxy compound, or a photopolymerizable compound such as an acrylate compound. The conductive filler 132 may include metal particles such as nickel (Ni) particles, cobalt (Co) particles, silver (Ag) particles, copper (Cu) particles, gold (Au) particles, or palladium (Pd) particles, and herein, copper (Cu) particles may be used.

The bonding portion 130 may be provided to couple a plurality of wiring portions 110 and 120, separately manufactured, and a multilayer substrate can be efficiently implemented therefrom. As the number of layers of a substrate increases, a defect rate increases, and a decrease in yield is particularly noticeable in a substrate requiring fine circuits. When a fine circuit process is required for a portion of wiring portions, such as a first wiring portion 110, the first wiring portion 110 may be relatively implemented as a fine circuit. In this case, by manufacturing a second wiring portion 120 in a process separate from the process of manufacturing the first wiring portion 110, a defect rate may be reduced as compared to the case in which the first wiring portion 110 and the second wiring portion 120 are manufactured at once. In this case, the second wiring portion 120 having a relatively wide pitch may also be manufactured in a relatively inexpensive process.

Further, in the embodiment, a first insulating film 141 was employed to reduce short circuit defects due to unintended electrical connection in a region in which the first wiring portion 110 and the second wiring portion 120 are connected to each other. The first insulating film 141 may be formed in a portion of the first conductor layer 112, and for example, may be formed in the remaining region of the second conductor layer 122, except for a pad region connected to the first conductor layer 112. The first insulating film 141 may be in contact with a conductive filler 132 of the bonding portion 130. The first insulating film 141 may be coated on a portion of the first conductor layer 112. Alternatively, the first insulating film 141 may be a surface oxide layer of the first conductor layer 112. In this case, the surface oxide layer may include an oxide of a metal included in the first conductor layer 112. When the first conductor layer 112 is protected by the first insulating film 141, the first conductor layer 112 may be effectively electrically protected in the remaining region of the wiring portions 110 and 120, except for a connection region of the wiring portions 110 and 120, so that electrical reliability of the printed circuit board 100 may be improved. In addition, in order to further improve the reliability, a second insulating film 142 may be further provided, and the second insulating film 142 may be formed in a portion of the second conductor layer 122. For example, the second insulating film 142 may be formed in a remaining region of the second conductor layer 122, except for a pad region connected to the first conductor layer 112. The second insulating film 142 may be in contact with the conductive filler 132 of the bonding portion 130.

The first insulating film 141 may be formed to have a thin thickness while maintaining high electrical insulation properties. Considering the same, the first insulating film 141 may include at least one of Al₂O₃, ZnO, TiO₂, and SiO₂. The first insulating film 141 may be implemented thinner than other components, and for example, a thickness of the first insulating film 141 may be 5 nm to 15 nm. As an example of a method for forming the first insulating film 141, the first insulating film 141 may be an atomic layer deposition layer obtained using atomic layer deposition. When the first insulating film 141 is an atomic layer deposition layer, it can be formed of Al₂O₃, and from thereamong, Al₂O₃ can have high insulating properties and adhesion. However, other vapor deposition processes may also be used. Likewise, a second insulating film 142 may be coated on a portion of the second conductor layer 212. Alternatively, the second insulating film 142 may be a surface oxide layer of the second conductor layer 122. In this case, the surface oxide layer may include an oxide of a metal included in the second conductor layer 122. The second insulating film 142 may be formed to have a thin thickness while maintaining high electrical insulation properties. Considering the same, the second insulating film 142 may include at least one of Al₂O₃, ZnO, TiO₂, and SiO₂. The second insulating film 142 may be implemented thinner than other components, and for example, a thickness of the second insulating film 142 may be 5 nm to 15 nm. As an example of a method for forming the second insulating film 142, the second insulating film 142 may be an atomic layer deposition layer obtained using atomic layer deposition. However, other vapor deposition processes may also be used.

As in the illustrated form, the first insulating film 141 may also be formed on one surface of the first insulating layer 111 in addition to the first conductor layer 112, thereby further reducing the possibility of a short circuit occurring. In addition, the second insulating film 142 may also be formed one surface of the second insulating layer 121 in addition to the second conductor layer 122, thereby further reducing the possibility of a short circuit occurring. Alternatively, the first insulating film 141 may be limited to a minimum region to prevent unintended electrical connection between the first conductor layer 112 and the second conductor layer 122. In this case, as in the modified example of FIG. 8, the first insulating film 141 may be implemented in a form exposing at least a portion of one surface of the first insulating layer 111. Similarly, the second insulating film 142 may be implemented in a form exposing at least a portion of one side of the second insulating layer 121. Meanwhile, in FIGS. 3 and 8, the first insulating film 141 may open the entire pad region of the first conductor layer 112, but the first insulating film 141 may extend to one surface of the first conductor layer 112 to reduce a width of the exposed region in the pad region of the first conductor layer 112, i.e., to reduce an area of the exposed region of the first conductor layer 112 (e.g., the embodiment of FIG. 10). Similarly, the second insulating film 142 may extend to one surface of the second conductor layer 122 to reduce a width of the exposed region in the pad region of the second conductor layer 122, i.e., to reduce an area of the exposed region of the second conductor layer 122.

Referring to FIG. 3, electrical connection between the first wiring portion 110 and the second wiring portion 120 may be performed in a region in which the first insulating film 141 and the second insulating film 142 are not formed. Specifically, a first exposed region R1 in which a first insulating film 141 is not formed in the first conductor layer 112 and a second exposed region R2 in which a second insulating film 142 is not formed in the second conductor layer 122 may be connected by a conductive filler 132. In this case, although only one first exposed region R1 and one second exposed region R2 are illustrated in FIG. 3, respectively, which may be a portion of the printed circuit board 100, and each of the plurality of first exposed regions R1 and the plurality of first exposed regions R2 may be provided.

As an additional component, the first wiring portion 110 may further include a third conductor layer 114 disposed on the other surface (upper surface based on FIG. 3) opposite to one surface of the first insulating layer 111 on which the first conductor layer 112 is formed, and a third insulating film 143 formed on a portion of the third conductor layer 114. In addition, the second wiring portion 120 may further include a fourth conductor layer 124 disposed on the other surface (lower surface based on FIG. 3) opposite to one surface of the second insulating layer 121 on which the second conductor layer 122 is formed and a fourth insulating film 144 formed on a portion of the fourth conductor layer 124. The third and fourth insulating films 143 and 144 may include the same material as the first and second insulating films 141 and 142, and further, may be formed by the same process as the first and second insulating films 141 and 142.

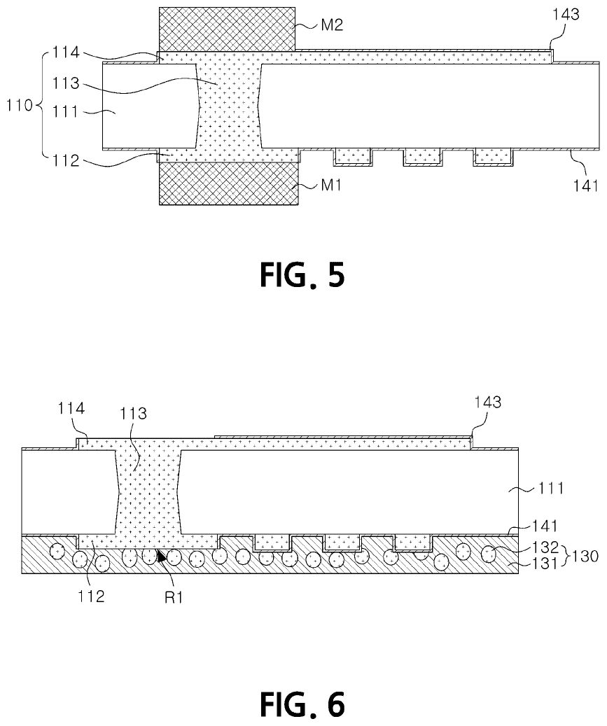

An example of a manufacturing process of a printed circuit board will be described with reference to FIGS. 4 to 7, focusing on a bonding process of the first and second wiring portions 110 and 120. First, after the first wiring portion 110 is prepared, a mask M1 covering a portion of the first conductor layer 112 may be formed (FIG. 4), and a region covered by the mask M1 may be a region in which the first insulating film 141 is not formed and is exposed. In addition, a mask M2 covering a portion of the third conductor layer 114 may be formed. The masks M1 and M2 may include a metal having different etching characteristics from the conductor layers 112 and 114. Next, a first insulating film 141 covering the first conductor layer 112 and a third insulating film 143 covering the third conductor layer 114 are formed (FIG. 5). The insulating films 141 and 143 may include at least one of materials having excellent insulating properties even at relatively thin thicknesses, such as Al₂O₃, ZnO, TiO₂, and SiO₂, and may be formed through a process such as atomic layer deposition. In FIG. 5, the insulating films 141 and 143 may not be formed on a side surface of the first insulating layer 111, but, unlike this, the insulating films 141 and 143 may also be formed on the side surface of the first insulating layer 111. However, in a dicing process of a panel to be described later, the insulating films 141 and 143 may not exist on a side surface of the unit printed circuit board.

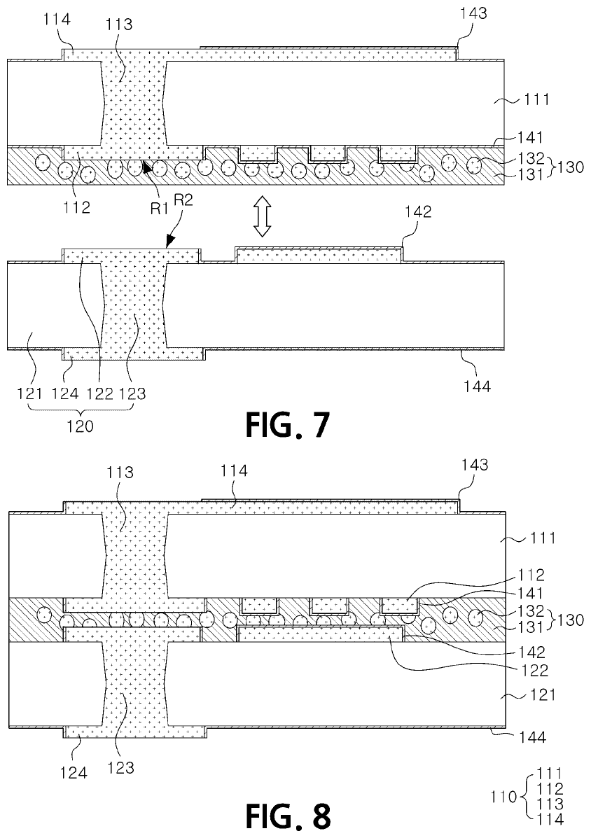

Next, the masks M1 and M2 are removed to expose portions of the first conductor layer 112 and the third conductor layer 114, and a bonding portion 130 is attached to one side of the first wiring portion 110 (FIG. 6). The masks M1 and M2 may be removed through a dry or wet etching process that can be used in the art, such as plasma etching, or the like. The bonding portion 130 may be a semi-cured or uncured bonding layer 131 having a conductive filler 132 therein. The second wiring portion 120 may be prepared by the same process as the first wiring portion 110, and the first and second wiring portion 110 and 120 may be bonded by applying pressure thereto while the bonding portion 130 is disposed between the first and second wiring portions 110 and 120 thus obtained (FIG. 7). By using a formula of bonding the first and second wiring portions 110 and 120 using a bonding portion 130, a method of hybrid bonding Cu layers to Cu layers may be replaced.

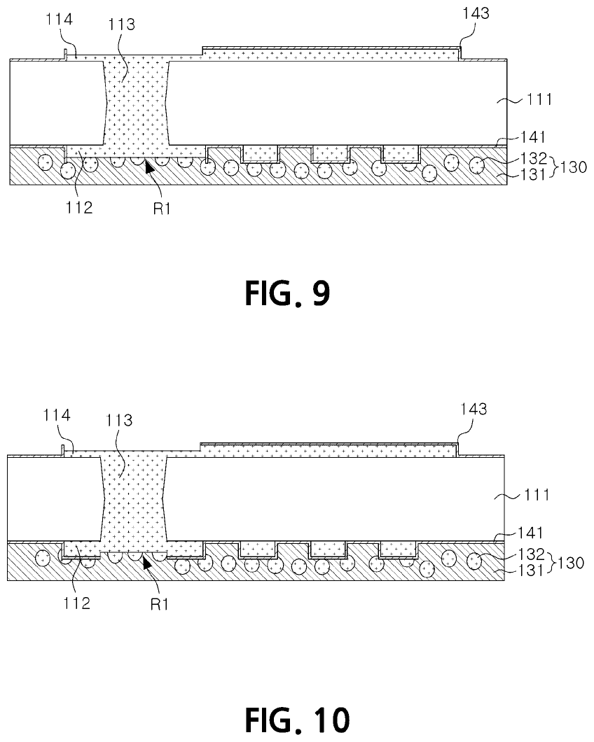

A printed circuit board according to modified embodiments with reference to FIGS. 9 to 16 will be described. First, in the embodiment of FIG. 9, a region of the first conductor layer 112 in which the first insulating film 141 is formed is thicker than a region of the first conductor layer 112 in which the first insulating film 141 is not formed. In other words, the exposed region R1 of the first conductor layer 112 may be relatively thin. This may be formed by over-etching in which a portion of the first conductor layer 112 is removed together in a process of removing the mask M1 during the manufacturing process described above. In this case, an etching amount of the first conductor layer 112 may be adjusted according to the size of the intended step structure, and for example, about 2 μm may be removed. Similarly thereto, in a process of removing the mask M2, a portion of the third conductor layer 114 may be removed together, and accordingly, a region of the third conductor layer 114 not covered by the third insulating film 143 may have a relatively thin thickness.

As the first conductor layer 112 is partially removed, the region of the first conductor layer 112 in which the first insulating film 141 is not formed may have a step structure. Accordingly, the bonding portion 130 may be in contact with a surface of the region R1 of the first conductor layer 112 in which the first insulating film 141 is not formed and a side surface of the first insulating film 141, so that the bonding property between the first conductor layer 112 and the bonding portion 130 may be improved. Similarly thereto, as the third conductor layer 114 is partially removed, a region of the third conductor layer 114 in which the third insulating film 143 is not formed may have a step structure. As an example of such a step structure, as in the embodiment of FIG. 10, the region R1 of the first conductor layer 112 in which the first insulating film 141 is not formed may have a groove shape. In this case, the bonding portion 130 may be filled in the groove-shaped region of the first conductor layer 112. In addition, although not illustrated in FIG. 10, a region of the third conductor layer 114 in which the third insulating film 143 is not formed may also be implemented as a groove shape. Although the description is provided based on the first conductor layer 112 in FIGS. 9 and 10, the same structure may also be applied to the second conductor layer 122. Although the description is provided based on the first conductor layer 112 in FIGS. 9 and 10, the same structure may also be adopted for the second conductor layer 122.

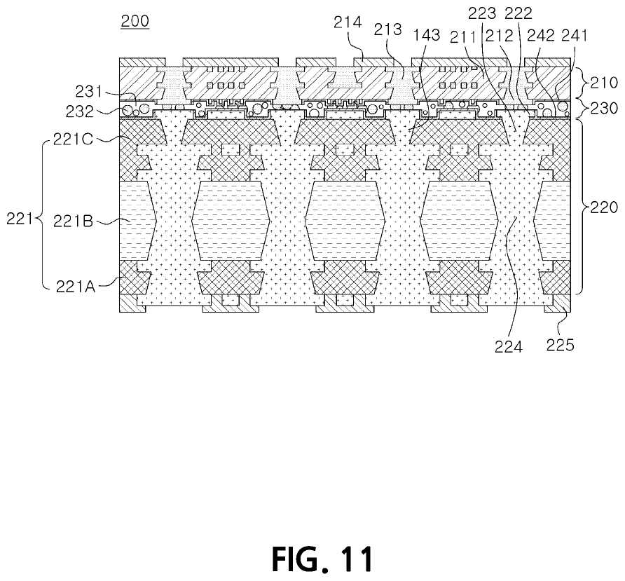

The embodiment of FIG. 11 illustrates a more specific structure of the first wiring portion 210 and the second wiring portion 220. In the embodiment, the printed circuit board 200 has a first wiring portion 210 and a second wiring portion 220 connected to each other by a bonding portion 230, and the first wiring portion 210 and the second wiring portion 220 have different structures. The first wiring portion 210 may include a first insulating layer 211 and a first conductor layer 212, and in each layer, a plurality of layers are stacked. The first insulating layer 211 may include an insulating material, such as a thermosetting resin such as an epoxy resin, a thermoplastic resin such as a polyimide, or a material in which these resins are mixed with an inorganic filler such as silica, or a resin impregnated into a core material such as glass fiber (glass cloth, glass fabric) together with an inorganic filler, for example, Ajinomoto build-up film (ABF), prepreg, or the like. If necessary, the first insulating layer 211 may include a Photo Imageable Dielectric (PID). The first insulating layer 211 may be obtained by stacking a plurality of insulating layers, wherein the plurality of insulating layers may include the same or different insulating materials.

The first conductor layer 212 may include a metal material such as copper (Cu), aluminum (Al), silver (Ag), tin (Sn), gold (Au), nickel (Ni), lead (Pb), titanium (Ti), or an alloy thereof. The first conductor layer 212 may include an electroless plating layer and an electrolytic plating layer, and may further include a copper foil if necessary. The first conductor layer 212 may perform various functions depending on the design of a corresponding layer. For example, the first conductor layer 212 may include a ground pattern, a power pattern, a signal pattern, or the like. Here, the signal pattern may include various signals, such as a data signal, other than a ground pattern, a power pattern, or the like. Each of the patterns may include a trace, a plane, and/or a pad.

A first via 213 may be provided to connect the first conductor layers 212. The first via 113 may include copper (Cu), aluminum (Al), silver (Ag), tin (Sn), gold (Au), nickel (Ni), lead (Pb), titanium (Ti), or an alloy thereof as a metal material. The first via 213 may be formed together with the first conductor layer 212, and may include an electroless plating layer and an electrolytic plating layer. The first via 213 may be a filled-type via in which a through-hole of the first insulating layer 211 is filled with a metal material, but an example embodiment thereof is not limited thereto, and the first via 213 may also be a conformal-type via in which a metal material is disposed along a wall surface of the through-hole. The first via 213 may have a tapered shape in a cross-section. The first via 213 may perform various functions depending on the design of a corresponding layer. For example, the first via 213 may include a ground via, power via, signal via, or the like. Here, the signal via may include a via for transmitting various signals, such as a data signal, other than a ground via, a power via, or the like.

A first solder resist layer 214 may be disposed outwardly of the first wiring portion 210. The first solder resist layer 214 may have an opening which partially opens a first conductor layer 212 disposed in an uppermost portion of the first wiring portion 210 among the first conductor layers 212. The first solder resist layer 214 may include a generally used solder resist material and may include a photosensitive insulating material, an example but embodiment thereof is not limited thereto.

The second wiring portion 220 may include a second insulating layer 221 and a second conductor layer 222, and in each layer, a plurality of layers are stacked. The second insulating layer 221 may include a first core portion 221B and build-up portions 221A and 221C disposed above and below the first core portion 221B. The first core portion 221B may include an insulating material, such as a thermosetting resin such as an epoxy resin, a thermoplastic resin such as a polyimide, or a material in which these resins are mixed with an inorganic filler such as silica, or a resin impregnated into a core material such as glass fiber, glass cloth, glass fabric, or the like, together with an inorganic filler, for example, Ajinomoto build-up film (ABF), prepreg, or the like, but an example embodiment thereof is not limited thereto. If necessary, a core insulating layer of a different material, such as a glass substrate, or the like, may be introduced into the first core portion 221B, or a metal core layer may be used. The first core portion 221B may be provided with a through-via 224 to connect the second conductor layer 222 disposed thereabove and therebelow.

Build-up portions 221A and 221C may be respectively disposed on both sides of the first core portion 221B, and may have a multilayer structure. The build-up portions 221A and 221C may include an insulating material, such as a thermosetting resin such as an epoxy resin, a thermoplastic resin such as a polyimide, or a material in which these resins are mixed with an inorganic filler such as silica, or a resin impregnated into a core material such as glass fiber, glass cloth, glass fabric, or the like, together with an inorganic filler, for example, Ajinomoto build-up film (ABF), prepreg, or the like. If necessary, the build-up portions 221A and 221C may include a Photo Imageable Dielectric (PID). A region of the second insulating layer 221 forming the build-up portions 221A and 221C may be obtained by stacking a plurality of insulating layers, wherein the plurality of insulating layers may include the same or different insulating materials.

The second conductor layer 222 may include a metal material such as copper (Cu), aluminum (Al), silver (Ag), tin (Sn), gold (Au), nickel (Ni), lead (Pb), titanium (Ti), or an alloy thereof. The second conductor layer 222 may include an electroless plating layer and an electrolytic plating layer, and may further include a copper foil if necessary. The second conductor layer 222 may perform various functions depending on the design of a corresponding layer. For example, the second conductor layer 222 may include a ground pattern, a power pattern, a signal pattern, or the like. Here, the signal pattern may include various signals, such as a data signal, other than a ground pattern, a power pattern, or the like. Each of the patterns may include a trace, a plane, and/or a pad.

As in the present embodiment, when the second conductor layer 222 has a multilayer structure, a second via 223 may be provided to connect the same. The second via 223 may include a metal material such as copper (Cu), aluminum (Al), silver (Ag), tin (Sn), gold (Au), nickel (Ni), lead (Pb), titanium (Ti), or an alloy thereof. The second conductor layer 222 may include an electroless plating layer and an electrolytic plating layer, and may further include a copper foil if necessary. The second via 223 may be formed together with the second conductor layer 222, and may include an electroless plating layer and an electrolytic plating layer. The second via 223 may be a filled-type via in which a through-hole of the second insulating layer 221 is filled with a metal material, but is not limited thereto, and may also be a conformal-type via in which the metal material is disposed along a wall surface of the through-hole. The second via 223 may have a tapered shape in a cross-section. The second via 223 may perform various functions depending on the design of a corresponding layer. For example, the second via 223 may include a ground via, a power via, a signal via, or the like. Here, the signal via may include vias for transmitting various signals, such as a data signal, other than a ground via, a power via, or the like.

In the case of the first wiring portion 210, the first conductor layer 212 provided therein may be implemented to have a relatively narrow pitch as compared to the second conductor layer 222 of the second wiring portion 220 through a fine circuit process. In this case, by manufacturing a second wiring portion 220 in a process separate from the process of manufacturing the first wiring portion 210, a defect rate may be reduced as compared to the case in which the first wiring portion 210 and the second wiring portion 220 are manufactured at once. In this case, the second wiring portion 220 having a relatively wide pitch may also be manufactured in a relatively inexpensive process.

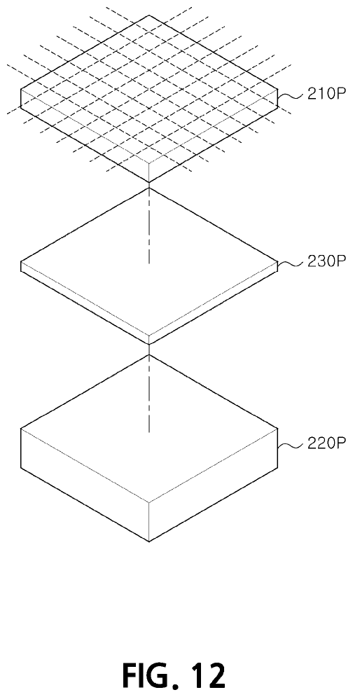

Similarly to the embodiment described above, the bonding portion 230 includes a bonding layer 231 and a conductive filler 232, and is provided with a first insulating film 241 formed on a portion of the first conductor layer 212. Similarly, a second insulating film 242 formed in a portion of the second conductor layer 222 may be provided. In this case, as in the illustrated form, the first insulating film 241 may not be formed on a side surface of the first insulating layer 211, and the second insulating film 242 may not be formed on a side surface of the second insulating 221. A process of obtaining this structure is described with reference to FIG. 12. The first wiring portion 210 and the second wiring portion 220 may be implemented in a panel form, as illustrated in FIG. 12. That is, a first panel 210P and a second panel 220P may be bonded by an adhesive panel 230P, and a unit printed circuit board may be obtained by cutting the first panel 210P and the second panel 220P along a dicing line (dotted line). In this case, after dicing, there is no insulating film on a side surface of the unit printed circuit board. In addition, in the case of this manufacturing method, as illustrated in FIG. 11, the widths of the first insulating layer 211 and the second insulating layer 221 may be substantially the same.

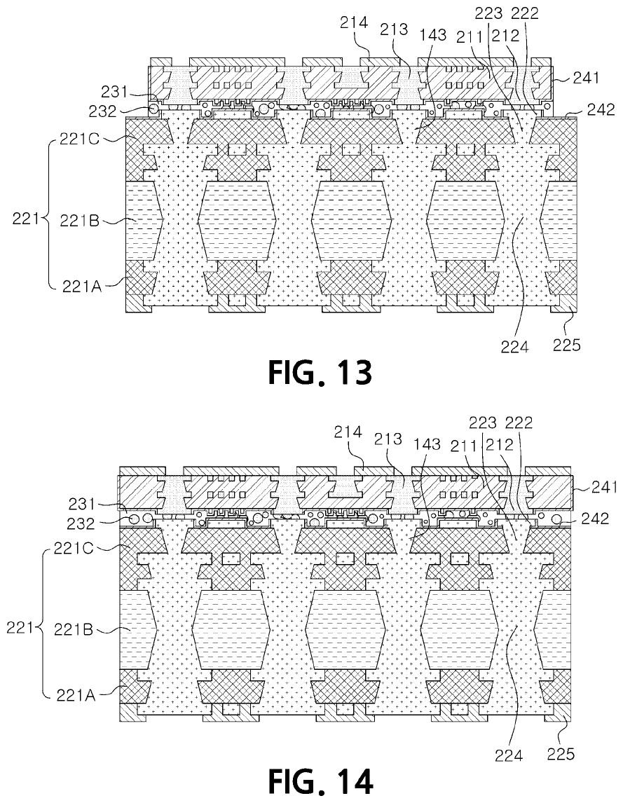

Alternatively, as in the embodiment of FIG. 13, a structure in which the first insulating film 241 extends to the side surface of the first insulating layer 211 and the second insulating film 242 is not formed on the side surface of the second insulating layer 221 may be illustrated. Such a structure may be obtained by forming the first insulating film 241 in a first wiring portion 210 in a unit state without using a method of bonding the first and second wiring portions 210 and 220 and then dicing the same. For example, this is a case in which a method of bonding a first wiring portion 210 in a unit state and a second wiring portion 220 in a panel state and then dicing the second wiring portion 220 is used. In this case, the width of the first insulating layer 211 may be narrower than the width of the second insulating layer 221. When the first insulating film 241 is also formed on the side surface of the first insulating layer 211, the insulation properties of the first wiring portion 210 may be improved overall.

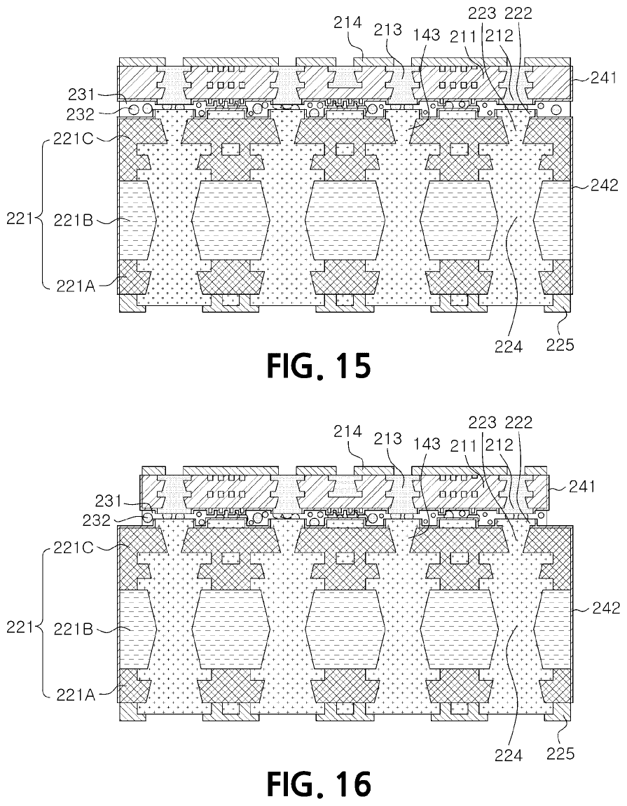

Meanwhile, a structure as illustrated in FIG. 13 is not only obtained when a second wiring portion 220 is manufactured in a panel form and then diced. The second wiring portion 220 may also be bonded to the first wiring portion 210 in a unit state after dicing, that is, in a unit state. In addition, even when a first insulating film 241 extends to a side surface of the first insulating layer 211 in the first wiring portion 210, the width of the first insulating layer 211 and the width of the second insulating layer 221 may be substantially the same, as in the form illustrated in FIG. 14. In addition, as in the embodiment of FIG. 15, even when the width of the first insulating layer 211 and the width of the second insulating layer 221 are substantially the same, both the first insulating film 241 and the second insulating film 242 may be extended. That is, in addition to the first insulating film 241, the second insulating film 242 may also extend to a side surface of the second insulating layer 221. Furthermore, as illustrated in FIG. 16, when the width of the first insulating layer 211 is narrower than the width of the second insulating layer 221, the first insulating film 241 may extend to the side surface of the first insulating layer 211, and the second insulating film 242 may extend to the side surface of the second insulating layer 221.

In the present disclosure, the meaning on a cross-section may refer to a cross-sectional shape when an object is cut vertically, or a cross-sectional shape when the object is viewed from the side. Furthermore, the meaning on a plane may refer to a planar shape when the object is horizontally cut, or a planar shape when the object is viewed from the top or the bottom.

In the present disclosure, for convenience, an upper side, an upper portion, and an upper surface are used to refer to a downward direction with respect to a cross-section of a drawing, and a lower side, a lower portion, and a lower surface are used to refer to an opposite direction thereof. However, this is a definition of direction for the convenience of explanation, and the scope of the claim is not specifically limited by the description of this direction, and the concept of upper/lower may be changed at any time.

In the present disclosure, a meaning of being connected is a concept including not only directly connected but also indirectly connected through an adhesive layer or the like. Furthermore, a meaning of electrically connected is a concept including both physically connected and not connected. In addition, expressions such as first and second are used to distinguish one component from another, and do not limit the order and/or importance of the components. In some cases, a first component may be referred to as a second component without departing from the scope of rights, or similarly, the second component may be referred to as the first component.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

As set forth above, in the printed circuit board according to an embodiment of the present disclosure, reliability may be improved in coupling a plurality of wiring portions to each other.

While the example embodiments have been illustrated and described above, it will be apparent to those skilled in the art that modifications and variations could be made without departing from the scope of the present disclosure as defined by the appended claims.

What is claimed is:

1. A printed circuit board, comprising:
a first wiring portion including a first insulating layer and a first conductor layer disposed on at least one surface of the first insulating layer;
a second wiring portion including a second insulating layer and a second conductor layer disposed on at least one surface of the second insulating layer facing the one surface of the first insulating layer;
a bonding portion disposed between the first and second wiring portions to connect the first and second wiring portions, and including a bonding layer and a conductive filler dispersed within the bonding layer; and
a first insulating film disposed on a portion of the first conductor layer.

2. The printed circuit board of claim 1, wherein the first insulating film includes at least one of Al₂O₃, ZnO, TiO₂, and SiO₂.

3. The printed circuit board of claim 1, wherein the first insulating film is an atomic layer deposition layer.

4. The printed circuit board of claim 1, wherein the first insulating film has a thickness of 5 nm to 15 nm.

5. The printed circuit board of claim 1, wherein the first insulating film is also disposed on the one surface of the first insulating layer.

6. The printed circuit board of claim 1, wherein the first insulating film exposes at least a portion of the one surface of the first insulating layer.

7. The printed circuit board of claim 1, wherein the first insulating film is in contact with the conductive filler.

8. The printed circuit board of claim 1, wherein the first insulating film is coated on a portion of the first conductor layer.

9. The printed circuit board of claim 1, wherein the first insulating film is a surface oxide layer of the first conductor layer.

10. The printed circuit board of claim 1, wherein a region of the first conductor layer on which the first insulating film is disposed is thicker than a region of the first conductor layer which is free of the first insulating film.

11. The printed circuit board of claim 10, wherein the bonding portion is in contact with a surface of the region of the first conductor layer which is free of the first insulating film and a side surface of the first insulating film.

12. The printed circuit board of claim 10, wherein the region of the first conductor layer which is free of the first insulating film has a step structure with respect to the region of the first conductor layer on which the first insulating film is disposed.

13. The printed circuit board of claim 10, wherein the region of the first conductor layer which is free of the first insulating film has a groove shape with respect to the region of the first conductor layer on which the first insulating film is disposed.

14. The printed circuit board of claim 13, wherein the bonding portion is disposed in the groove-shaped region of the first conductor layer.

15. The printed circuit board of claim 1, wherein a pitch of the first conductor layer is narrower than a pitch of the second conductor layer.

16. The printed circuit board of claim 1, wherein the second wiring portion further includes a second insulating film disposed on a portion of the second conductor layer.

17. The printed circuit board of claim 16, wherein a first exposed region of the first conductor layer exposed by the first insulating film and a second exposed region of the second conductor layer exposed by the second insulating film are connected by the conductive filler.

18. The printed circuit board of claim 16, wherein a side surface of the first insulating layer is free of the first insulating film, and
a side surface of the second insulating layer is free of the second insulating film.

19. The printed circuit board of claim 18, wherein widths of the first insulating layer and the second insulating layer are substantially the same.

20. The printed circuit board of claim 16, wherein the first insulating film extends to a side surface of the first insulating layer, and
a side surface of the second insulating layer is free of the second insulating film.

21. The printed circuit board of claim 20, wherein a width of the first insulating layer is narrower than a width of the second insulating layer.

22. The printed circuit board of claim 1, wherein the first wiring portion further includes a third conductor layer disposed on the other surface of the first insulating layer opposite to the one surface of the first insulating layer, and a third insulating film disposed on a portion of the third conductor layer.

23. The printed circuit board of claim 22, wherein the second wiring portion further includes a fourth conductor layer disposed on the other surface of the second insulating layer opposite to the one surface of the second insulating layer, and a fourth insulating film disposed on a portion of the fourth conductor layer.
